(19) United States
(12) Patent Application Publication
(10) Pub. No.: US 2009/0154122 A1
(43) Pub. Date: Jun. 18, 2009

(54) Mechanical component-containing board and method of manufacturing same

(75) Inventor: Naoki Makamura, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/379,199

(22) Filed: Feb. 13, 2009

Related U.S. Application Data
(63) Continuation of application No. PCT/JP2006/316111, filed on Aug. 16, 2006.

(51) Int. Cl. H05K 1/18; B23P 19/00

(52) U.S. Cl. 361/761; 29/739

(57) ABSTRACT

A mechanical component-containing board includes a board body and a mechanical component having a part thereof built in and integrated with the board body.

### CROSS-REFERENCE TO RELATED APPLICATION(S)

The present application is a continuation application filed under 35 U.S.C. 111(a) claiming benefit under 35 U.S.C. 120 and 365(c) of PCT International Application No. PCT/JP2006/316111, filed on Aug. 16, 2006, the entire contents of which are incorporated herein by reference.

### FIELD

A certain aspect of the embodiment(s) discussed herein is related to a mechanical component-containing board having a mechanical component built in and integrated with a substrate and a method of manufacturing the mechanical component-containing board.

### BACKGROUND

In these years, there has been a strong demand for reduction in the size, thickness, and cost of electronic apparatuses typified by portable terminals, so that there has also been a demand for reduction in the size, thickness, and cost of circuit boards provided in electronic apparatuses and of various components mounted on circuit boards.

The components mounted on circuit boards are roughly classified into passive components, active components, and mechanical components. Here, passive components refer to electronic components that basically output an input signal without changing it, such as resistors, capacitors, and inductors. Active components refer to electronic components having the function of changing the basic characteristics of an input signal during their operations. On the other hand, mechanical components refer to components that play a mechanical role for operating or holding a circuit, such as dials and switches or sockets and connectors.

In order to reduce the size and thickness of electronic apparatuses, it is desirable to reduce the size and thickness of passive components, active components, and mechanical components mounted on circuit boards. As discussed in, for example, Japanese Laid-Open Patent Publication No. 2005-135998, it has been proposed conventionally to reduce the size and thickness of electronic apparatuses by having passive components and active components built in and integrated with a circuit board.

However, no sufficient consideration is given to reduction in the size and thickness of mechanical components. FIG. 1 is a diagram illustrating a conventional common mounting structure of mechanical components. As illustrated in FIG. 1, it is a common practice to mount a connector 2 and a switch 3, which are mechanical components, on the surface of a substrate 1. A flexible printed circuit (FPC) board 4 is connected to the connector 2.

In the mounting structure of mechanical components illustrated in FIG. 2, a connector 5 is mounted on the substrate 1 as a mounting component. The connector 5 has connector terminals 7 provided in a housing 6.

Simply mounting the connector 2 on the surface of the substrate 1 results in an increase in the vertical size as illustrated in FIG. 1. Therefore, in the mounting structure illustrated in FIG. 2, a hollow is formed in part of the substrate 1 and the connector 5 is provided in this hollow. This configuration makes it possible to reduce the thickness by the amount of insertion of the connector 5 into the hollow. Further, there has been developed recently a configuration as illustrated in FIG. 3, where the substrate 1 has a laminated structure of bases 1a, 1b, and 1c stacked in layers and has the connector 5 built therein. In FIG. 3, reference numeral 8 denotes patterns, and reference numeral 9 denotes an electronic component.

According to the configurations illustrated in FIG. 2 and FIG. 3, however, the substrate 1 and the connector 5 are separate bodies, so that reduction in size and thickness has its limits. Further, an increase in cost is inevitable because the substrate 1 and the connector 5, which are manufactured separately, are prepared to mount the connector 5 on the substrate 1.

### SUMMARY

According to an aspect of an embodiment of the invention, a mechanical component-containing board includes a board body and a mechanical component having a part thereof built in and integrated with the board body.

According to an aspect of an embodiment of the invention, a method of manufacturing a mechanical component-containing board includes forming a plurality of bases having a pattern formed thereon, providing at least one of the bases with a part of a mechanical component, and forming a board body having the part of the mechanical component built therein and integrated therewith by stacking the bases in layers.

According to an aspect of an embodiment of the invention, a mechanical component-containing board includes a board body and a mechanical component, wherein the board body has a part thereof used as a part of the mechanical component.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWING(S)

FIG. 1 is a diagram illustrating a conventional board having mechanical components mounted thereon;

FIG. 2 is a diagram illustrating a conventional board having a mechanical component provided in a hollow of the board;

FIG. 3 is a cross-sectional view of a conventional board having a connector embedded therein;

FIG. 4 is a cross-sectional view of a mechanical component-containing board according to a first embodiment of the present invention;

FIG. 5A is a diagram for illustrating a method of manufacturing the mechanical component-containing board according to the first embodiment of the present invention, which is a cross-sectional view for illustrating a process for forming patterns;

FIG. 5B is a diagram for illustrating the method of manufacturing the mechanical component-containing board according to the first embodiment of the present invention, which is a cross-sectional view for illustrating a process for connecting a connector terminal;

FIG. 5C is a diagram for illustrating the method of manufacturing the mechanical component-containing board according to the first embodiment of the present invention, which is a cross-sectional view for illustrating a stacking process;

FIG. 5D is a diagram for illustrating the method of manufacturing the mechanical component-containing board according to the first embodiment of the present invention, which is a cross-sectional view for illustrating a process for patterning copper foil on board surfaces;

FIG. 5E is a diagram for illustrating the method of manufacturing the mechanical component-containing board according to the first embodiment of the present invention, which is a cross-sectional view for illustrating a process for mounting electronic components and a pressure contact component;

FIG. 6A is a diagram for illustrating another method of manufacturing the mechanical component-containing board according to the first embodiment of the present invention, which is a cross-sectional view for illustrating a process for forming patterns;

FIG. 6B is a diagram for illustrating the other method of manufacturing the mechanical component-containing board according to the first embodiment of the present invention, which is a cross-sectional view for illustrating a process for embedding a connector terminal with a dummy component;

FIG. 6C is a diagram for illustrating the other method of manufacturing the mechanical component-containing board according to the first embodiment of the present invention, which is a cross-sectional view for illustrating a stacking process;

FIG. 6D is a diagram for illustrating the other method of manufacturing the mechanical component-containing board according to the first embodiment of the present invention, which is a cross-sectional view for illustrating a process for forming patterns on board surfaces;

FIG. 6E is a diagram for illustrating the other method of manufacturing the mechanical component-containing board according to the first embodiment of the present invention, which is a cross-sectional view for illustrating a process for removing the dummy component;

FIG. 6F is a diagram for illustrating the other method of manufacturing the mechanical component-containing board according to the first embodiment of the present invention, which is a cross-sectional view for illustrating a process for mounting electronic components and a pressure contact component;

FIG. 7 is a cross-sectional view of a mechanical component-containing board according to a second embodiment of the present invention;

FIG. 8A is a diagram for illustrating a method of manufacturing the mechanical component-containing board according to the second embodiment of the present invention, which is a cross-sectional view for illustrating a process for forming patterns;

FIG. 8B is a diagram for illustrating the method of manufacturing the mechanical component-containing board according to the second embodiment of the present invention, which is a cross-sectional view for illustrating a stacking process;

FIG. 8C is a diagram for illustrating the method of manufacturing the mechanical component-containing board according to the second embodiment of the present invention, which is a cross-sectional view for illustrating a process for forming a switch part;

FIG. 8D is a diagram for illustrating the method of manufacturing the mechanical component-containing board according to the second embodiment of the present invention, which is a cross-sectional view for illustrating a process for mounting an electronic component;

FIG. 9 is a cross-sectional view of a mechanical component-containing board according to a third embodiment of the present invention;

FIG. 10A is a diagram for illustrating a method of manufacturing the mechanical component-containing board according to the third embodiment of the present invention, which is a cross-sectional view for illustrating a process for forming patterns;

FIG. 10B is a diagram for illustrating the method of manufacturing the mechanical component-containing board according to the third embodiment of the present invention, which is a cross-sectional view for illustrating a process for providing a dummy member and a stacking process;

FIG. 10C is a diagram for illustrating the method of manufacturing the mechanical component-containing board according to the third embodiment of the present invention, which is a cross-sectional view for illustrating a process for patterning copper foil on board surfaces;

FIG. 10D is a diagram for illustrating the method of manufacturing the mechanical component-containing board according to the third embodiment of the present invention, which is a cross-sectional view for illustrating a process for removing the dummy member;

FIG. 10E is a diagram for illustrating the method of manufacturing the mechanical component-containing board according to the third embodiment of the present invention, which is a cross-sectional view for illustrating a process for mounting electronic components and a pressure contact component;

FIG. 11 is a cross-sectional view of a mechanical component-containing board according to a fourth embodiment of the present invention;

FIG. 12A is a diagram for illustrating a method of manufacturing the mechanical component-containing board according to the fourth embodiment of the present invention, which is a cross-sectional view for illustrating a process for forming patterns;

FIG. 12B is a diagram for illustrating the method of manufacturing the mechanical component-containing board according to the fourth embodiment of the present invention, which is a cross-sectional view for illustrating a process for connecting a connector terminal;

FIG. 12C is a diagram for illustrating the method of manufacturing the mechanical component-containing board according to the fourth embodiment of the present invention, which is a cross-sectional view for illustrating a stacking process;

FIG. 12D is a diagram for illustrating the method of manufacturing the mechanical component-containing board according to the fourth embodiment of the present invention, which is a cross-sectional view for illustrating a process for patterning copper foil on board surfaces; and

FIG. 12E is a diagram for illustrating the method of manufacturing the mechanical component-containing board according to the fourth embodiment of the present invention, which is a cross-sectional view for illustrating a process for mounting electronic components and a pressure contact component.

### DESCRIPTION OF EMBODIMENT(S)

Preferred embodiment(s) of the present invention will be explained with reference to accompanying drawings.

### [a] First Embodiment

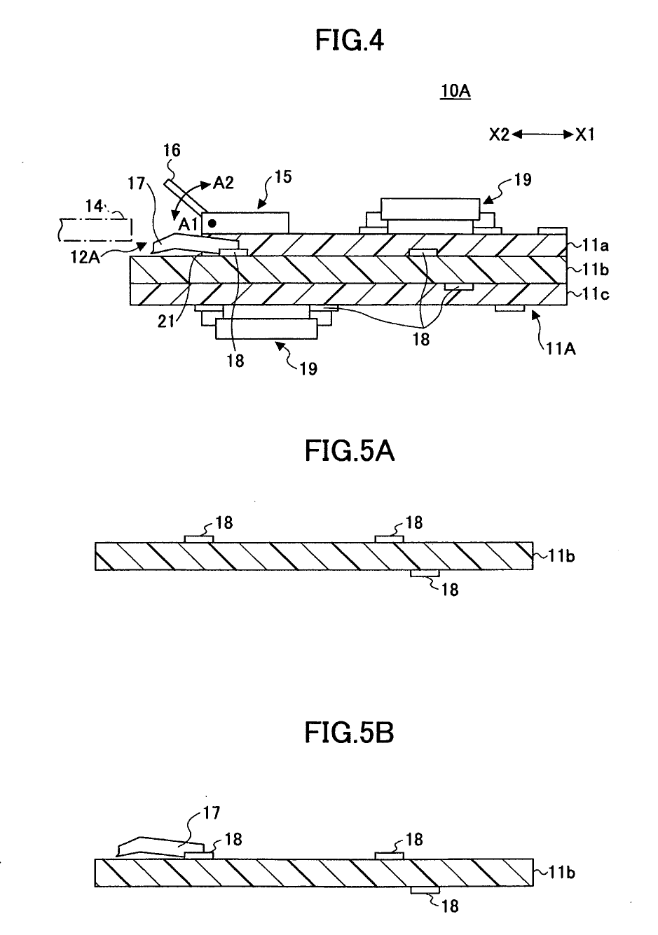

FIG. 4 is a cross-sectional view of a mechanical component-containing board 10A according to a first embodiment of the present invention. The mechanical component-containing board 10A includes a board body 11A, a connector part 12A, and electronic components 19.

The board body 11A is a multilayer substrate, and has a laminated structure of bases 11a, 11b, and 11c stacked in layers. The bases 11a through 11c are formed of an insulating material such as prepreg or an adhesive agent. In this embodiment, a configuration is illustrated where the three bases 11a through 11c are stacked. However, the number of base layers is not limited to three.

As described below, patterns 18 are preformed on each of the bases 11a through 11c. These patterns 18 serve as internal interconnects, and are formed by, for example, patterning a sheet (film) of conductive metal, such as copper foil, into a predetermined shape.

The connector part 12A is where a flexible printed circuit board (hereinafter referred to as “FPC”) 14, which is an attached device, is attached. The FPC 14 is attached to the connector part 12A in the X1 direction in FIG. 4, and is removed from the connector part 12A in the X2 direction in FIG. 4. The connector part 12A, which the FPC 14 is attached to and detached from, includes a pressure contact component 15, one or more connector terminals 17, and an opening part 21. For convenience of description, the connector terminals 17 are hereinafter collectively referred to as “connector terminal 17.”

The pressure contact component 15 is fixed on the upper surface of the board body 11A with an adhesive agent. This pressure contact component 15 includes a pressure contact part 16, which is turnable in the directions of arrows A1 and A2 in FIG. 4.

A spring mechanism (not graphically illustrated) is provided inside the pressure contact component 15 so as to allow the pressure contact part 16 to press and contact the FPC 14, thereby holding the FPC 14, when the pressure contact part 16 is turned in the direction of arrow A1 with the FPC 14 attached to the connector part 12A. This prevents the FPC 14 from being detached from the connector part 12A. Further, the pressure contact part 16 is locked at the position illustrated in FIG. 4 when turned in the direction of arrow A2. This locking of the pressure contact part 16 allows the FPC 14 to be attached to and detached from the connector part 12A with ease.

The connector terminal 17 serves as a connection terminal for the FPC 14. The connector terminal 17 is fixed to the board body 11A by being embedded in the base 11a of the board body 11A. Further, the connector terminal 17 is electrically connected to the patterns 18 formed on the base 11b. This connector terminal 17 is electrically connected to an electrode (not graphically illustrated) provided on the FPC 14 when the FPC 14 is connected to the connector 12A.

Each of the electronic components 19 is, for example, a chip capacitor or a chip resistor, and is mounted on the corresponding patterns 18 formed on the upper surface or lower surface of the board body 11A by surface mounting. These electronic components 19 may be built in the board body 11A.

As described above, the connector terminal 17 forms part of the connector part 12A. According to this embodiment, the connector terminal 17 is built in and integrated with the board body 11A by being embedded in the base 11a. That is, the connector terminal 17 and the board body 11A form a unit (unitary structure).

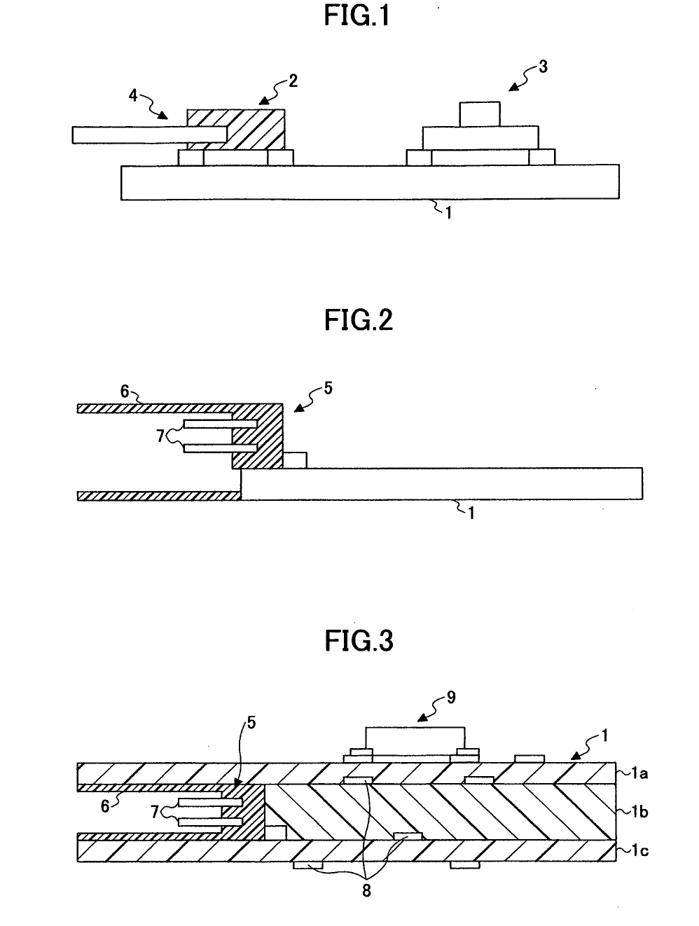

Thus, according to the mechanical component-containing board 10A of this embodiment, the connector terminal 17, which is part of the connector part 12A to serve as a mechanical component, is built in and integrated with the board body 11A. This allows the connector part 12A and the board body 11A to share their constituent component. Accordingly, it is possible to reduce the size and thickness of the mechanical component-containing board 10A, and it is possible to reduce product cost compared with the conventional configuration of manufacturing the connector 2 or 5 and the substrate 1 separately. (See FIG. 1 or FIG. 2.)

In the above description of this embodiment, the connector part 12A, which is a connecting unit, is taken as an example of the mechanical component to be built in the board body 11A. Alternatively, it is also possible to have another type of connecting unit (such as a socket) built in the board body 11A.

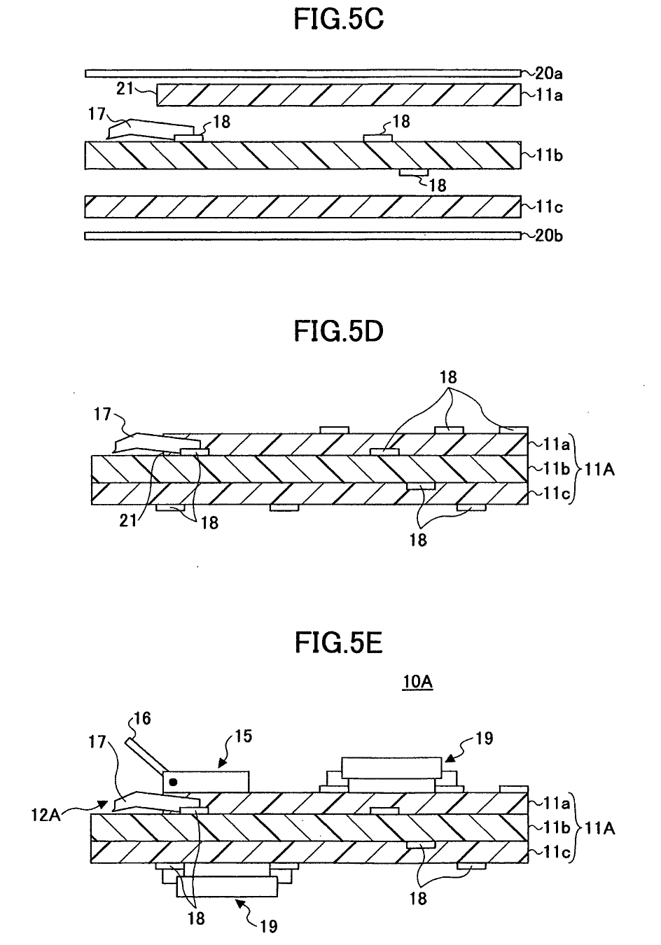

Next, a description is given, with reference to FIGS. 5A through 5E, of a method of manufacturing the mechanical component-containing board 10A. In manufacturing the mechanical component-containing board 10A, first, the base 11b is manufactured. Specifically, copper foil is provided on the top and bottom surfaces of prepreg or an adhesive agent to serve as the base material of the base 11b, and the copper foil is patterned into a predetermined shape using etching, thereby forming the patterns 18. FIG. 5A illustrates the base 11b having the patterns 18 formed thereon.

At this point, the patterns 18 are formed on the base 11b because the three-layer board body 11A is taken as an example in the description of this embodiment. However, in the case of a board body having four or more layers, the patterns 18 are formed on the bases except those of the topmost and bottommost layers.

When the base 11b is formed, next, the connector terminal 17 is provided on the base 11b. Specifically, in this embodiment, of the patterns 18 formed on the base 11b, the connector terminal 17 is electrically connected to one formed at the left position on the upper surface of the base 11b. The connector terminal 17 may be joined to this pattern 18 by soldering with a conductive metal or using a conductive adhesive agent. FIG. 5B illustrates a structure where the connector terminal 17 is provided on the base 11b, being joined to the corresponding pattern 18.

Once the connector terminal 17 is provided on the base 11b as described above, copper foil 20a, the base 11a, the base 11b, the base 11c, and copper foil 20b are stacked in layers in this order from top to bottom as illustrated in FIG. 5C. This layered body is subjected to joining processing while being pressed, so that the bases 11a through 11c are integrated into a unitary structure.

The copper foil 20a and the copper foil 20b are substantially equal in planar shape to the base 11b. Further, the base 11a is prepreg or an adhesive agent of a low-flow type, having the opening part 21 formed in a portion thereof to serve as part of the connector part 12A. The base 11c is prepreg or an adhesive agent, and is substantially equal in planar shape to the base material 11b.

By stacking the bases 11a through 11c in layers as described above, part of the connector terminal 17, specifically, an inside (right-side in FIG. 5D) portion of the connector terminal 17, is embedded between the base 11a and the base 11b.

When the above-described stacking process is completed, next, the copper foil 20a and the copper foil 20b are patterned by etching, so that the patterns 18 of predetermined shapes are formed on the upper surface of the base 11a and the lower surface of the base 11c. As a result, the board body 11A integrated with the built-in connector terminal 17, which forms part of the connector part 12A, is manufactured. FIG. 5D illustrates the manufactured board body 11A.

When the board body 11A is manufactured as described above, next, the pressure contact component 15 is mounted on the upper surface of the base 11a, and the electronic components 19 are mounted on the upper surface of the base 11a and the lower surface of the base 11c. As a result, the mechanical component-containing board 10A integrated with the built-in connector part 12A is completed as illustrated in FIG. 5E.

According to the above-described manufacturing method of this embodiment, the connector terminal 17 forming part of the connector part 12A is incorporated into the board body 11A during the manufacture of the board body 11A, thereby performing part of the manufacturing process of the connector part 12A and part of the manufacturing process of the board body 11A simultaneously. Therefore, it is possible to form the connector part 12A in the board body 11A in a shorter period of time and with more efficiency than the conventional method of mounting the connector 2 or 5 separately on the substrate 1. (See FIG. 1 or FIG. 2.) Further, according to the above-described manufacturing method of this embodiment, it is also possible to reduce manufacturing cost because of a simplified manufacturing process.

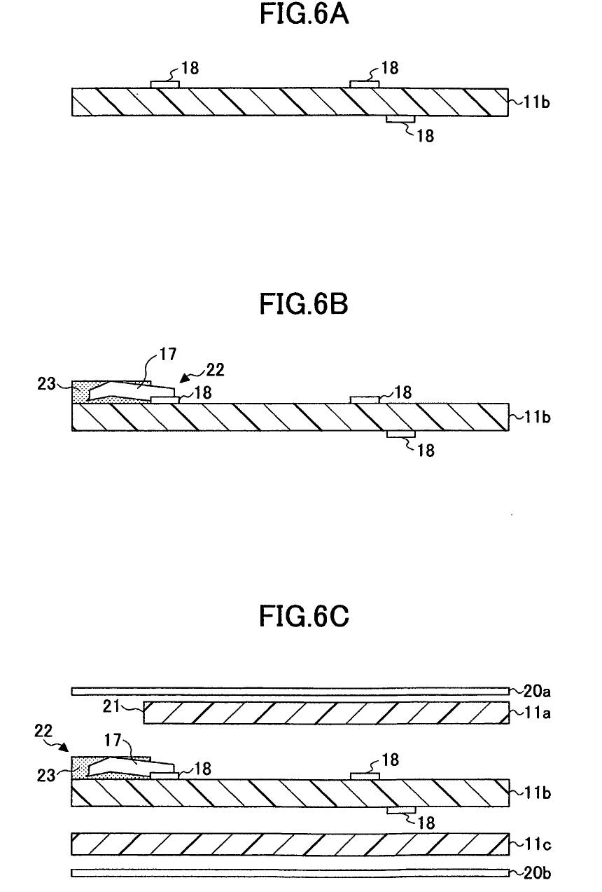

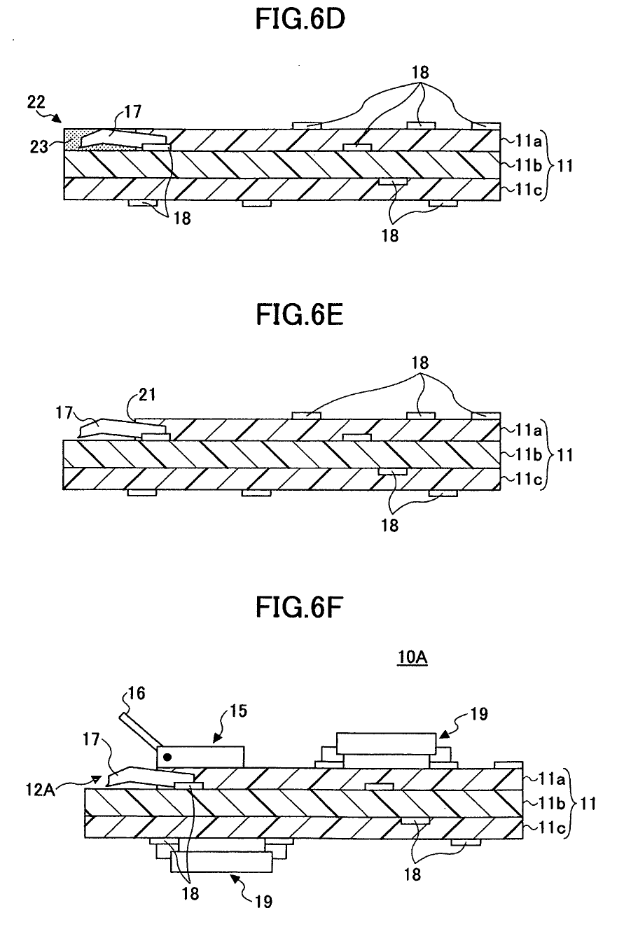

FIGS. 6A through 6F are diagrams for illustrating another method of manufacturing the mechanical component-containing board 10A according to this embodiment. In FIGS. 6A through 6F, elements or configurations corresponding to those illustrated in FIGS. 5A through 5E used for the above description are referred to by the same reference numerals, and further description thereof is omitted.

In this variation also, the base 11b is first manufactured in manufacturing the mechanical component-containing board 10A. FIG. 6A illustrates the base 11b having the patterns 18 formed thereon.

Next, the connector terminal 17 is provided on this base 11b. In this variation, the connector terminal 17 is fixed inside a dummy component 23, thus forming a connector terminal with a dummy component 22. This dummy component 23 is formed of resin or a metal material that can be dissolved by an etching agent.

As described above, the connector terminal 17 is fixed inside the dummy component 23. As a result, the presence of the dummy component 23 allows the connector terminal 17 to be self-supported on the base 11b, thus facilitating the positioning of the connector terminal 17 relative to the corresponding pattern 18. A predetermined portion (right-side portion in FIG. 6B) of the connector terminal 17 is exposed outside the dummy component 23.

Next, the portion of the connector terminal 17 exposed outside the dummy component 23 and the corresponding pattern 18 formed on the base 11b are electrically connected by soldering or with a conductive adhesive agent. FIG. 6B illustrates a structure where the connector terminal 17 is provided on the base 11b, being joined to the corresponding pattern 18.

When the connector terminal 17 is provided on the base 11b as described above, next, the copper foil 20a, the base 11a, the base 11b, the base 11c, and the copper foil 20b are stacked in this order from top to bottom as illustrated in FIG. 6C. This layered body is subjected to joining processing while being pressed, so that the bases 11a through 11c are integrated into a unitary structure.

By thus stacking the bases 11a through 11c in layers, the portion of the connector terminal 17 exposed outside the dummy component 23 is embedded and fixed between the base 11a and the base 11b. Further, since the dummy component 23 is substantially equal in thickness to the base 11a, the upper surface of the dummy component 23 is substantially level with the upper surface of the base 11a with the bases 11a through 11c being stacked in layers.

When the above-described stacking process is completed, next, the copper foil 20a and the copper foil 20b are patterned by etching, so that the patterns 18 of predetermined shapes are formed on the upper surface of the base 11a and the lower surface of the base 11c. FIG. 6D illustrates a structure where the patterns 18 are formed on the upper surface of the base 11a and the lower surface of the base 11c.

Next, the dummy component 23 is removed. As described above, the dummy component 23 is formed of resin or a metal material that can be dissolved by an etching agent. Therefore, the dummy component 23 can be removed by etching with an etching agent. As this etching agent, one formed of a material that affects neither the bases 11a through 11c nor the patterns 18 is selected.

By the completion of the removal of the dummy component 23, the board body 11A integrated with the built-in connector terminal 17 forming part of the connector part 12A is manufactured. FIG. 6E illustrates the manufactured board body 11A.

Next, the pressure contact component 15 is mounted on the upper surface of the base 11a, and the electronic components 19 are mounted on the upper surface of the base 11a and the lower surface of the base 11c. As a result, the mechanical component-containing board 10A integrated with the built-in connector part 12A is completed as illustrated in FIG. 6F.

As described above, according to the manufacturing method of this variation, the connector terminal with a dummy component 22 is used to facilitate the process of joining the connector terminal 17 to the base 11b. Therefore, according to the manufacturing method of this variation, it is possible to manufacture the mechanical component-containing board 10A with more ease.

### [b] Second Embodiment

Next, a description is given of a mechanical component-containing board 10B according to a second embodiment of the present invention.

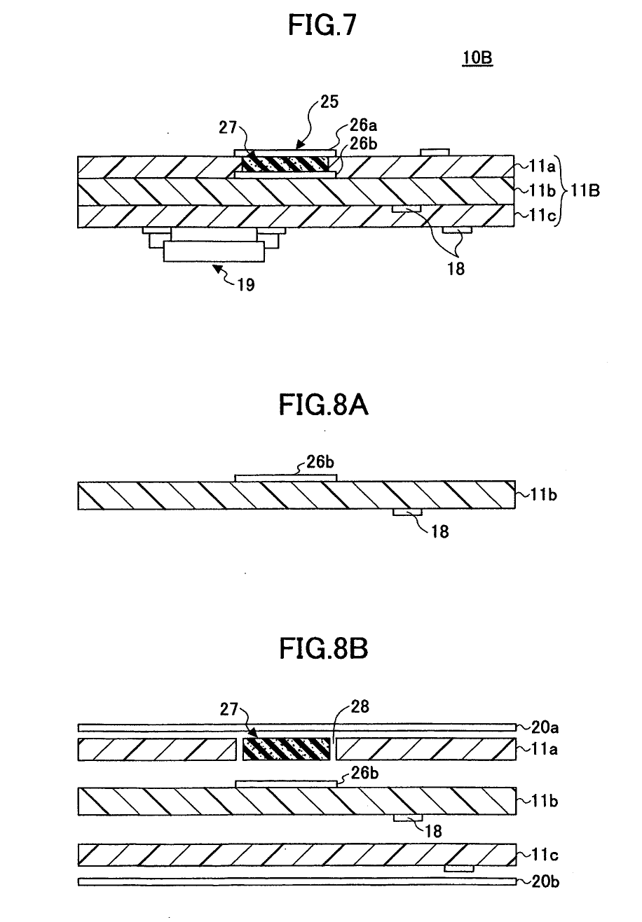

FIG. 7 is a cross-sectional view of the mechanical component-containing board 10B according to the second embodiment. In FIG. 7, elements or configurations corresponding to those of the mechanical component-containing board 10A of the first embodiment illustrated in FIG. 4 are referred to by the same reference numerals, and further description thereof is omitted.

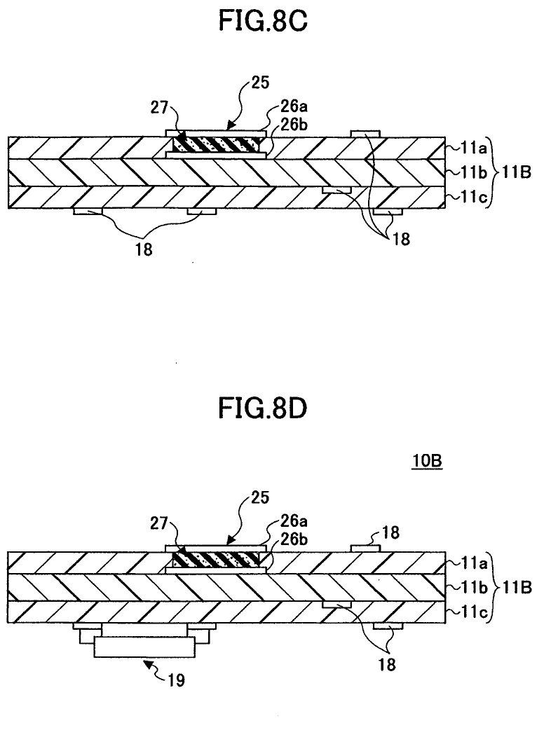

The mechanical component-containing board 10B according to this embodiment has a switch part 25 as a mechanical component built in a board body 11B. The switch part 25 includes a pair of switch electrodes 26a and 26b and an anisotropic conductive sheet 27 held (sandwiched) between these switch electrodes 26a and 26b. This anisotropic conductive sheet 27 is provided in an opening part 28 (FIG. 8B) formed in the base 11a.

The anisotropic conductive sheet 27 has conductive particles dispersed and mixed in a resin base. The conductive particles inside the resin base are kept apart from one another without application of pressure, but come into contact with one another to conduct in response to application of pressure.

Therefore, according to the mechanical component-containing board 10B of this embodiment, the anisotropic conductive sheet 27 conducts between the switch electrode 26a and the switch electrode 26b in response to a pressure applied to the anisotropic conductive sheet 27 when the switch electrode 26a is pressed from above in FIG. 7. According to this embodiment, the switch electrodes 26a and 26b of this switch part 25 are the same as the patterns 18 formed on and in the board body 11B. Therefore, the switch electrodes 26a and 26b are provided using part of the patterns 18.

Thus, in the mechanical component-containing board 10B according to this embodiment, part of the patterns 18 of the board body 11B is used directly as the switch electrodes 26a and 26b of the switch part 25, which is a mechanical component. This allows the switch part 25 and the board body 11B to share their constituent component. Accordingly, it is possible to reduce the size and thickness of the mechanical component-containing board 10B, and it is possible to reduce product cost compared with the conventional configuration of manufacturing the connector 2 or 5 and the substrate 1 separately. (See FIG. 1 or FIG. 2.)

In the above description of this embodiment, the switch part 25 having the anisotropic conductive sheet 27 provided between the switch electrodes 26a and 26b is taken as an example of the mechanical component to be built in the board body 11B. Alternatively, it is also possible to have a pressure sensor device such as a piezoelectric element provided between the switch electrodes 26a and 26b in place of the anisotropic conductive sheet 27. In the case of this configuration, since the piezoelectric element causes a potential difference corresponding to an applied pressure between opposed surfaces, a pressure sensor can be built in the board body 11B as a mechanical component.

Next, a description is given, with reference to FIGS. 8A through 8E, of a method of manufacturing the above-described mechanical component-containing board 10B. In FIGS. 8A through 8E, elements or configurations corresponding to those illustrated in FIGS. 5A through 5E used for the above description are referred to by the same reference numerals, and further description thereof is omitted.

In manufacturing the mechanical component-containing board 10B, first, the base 11b is manufactured. Specifically, copper foil is provided on the top and bottom surfaces of prepreg or an adhesive agent to serve as the base material of the base 11b, and the copper foil is patterned into a predetermined shape using etching, thereby forming the pattern 18 and the switch electrode 26b forming part of the switch part 25. FIG. 8A illustrates the base 11b having the pattern 18 and the switch electrode 26b formed thereon.

When the base 11b is formed, next, the copper foil 20a, the base 11a, the base 11b, the base 11c, and the copper foil 20b are stacked in layers in this order from top to bottom as illustrated in FIG. 8B. This layered body is subjected to joining processing while being pressed, so that the bases 11a through 11c are integrated into a unitary structure. The opening part 28 for providing the anisotropic conductive sheet 27 is preformed at a position where the switch part 25 is to be formed in the base 11a, and the stacking process is performed with the anisotropic conductive sheet 27 being attached inside this opening part 28. By thus stacking the bases 11a through 11c, the copper foil 20a, and the copper foil 20b in layers, the anisotropic conductive sheet 27 is opposed to each of the switch electrode 26b formed on the base 11b and the copper foil 20a (held [sandwiched] between the switch electrode 26b and the copper foil 20a).

When the above-described stacking process is completed, next, the copper foil 20a and the copper foil 20b are patterned by etching, so that the patterns 18 of predetermined shapes are formed on the upper surface of the base 11a and the lower surface of the base 11c and the switch electrode 26a forming part of the switch part 25 is formed on the upper surface of the base 11a. As a result, the board body 11B having part of the patterns 18 used directly as the switch electrodes 26a and 26b of the switch part 25, which is a mechanical component, is manufactured. FIG. 8C illustrates the manufactured board body 11B.

Once the board body 11B is manufactured as described above, the electronic component 19 is mounted on the lower surface of the base 11c, so that the mechanical component-containing board 10B integrated with the built-in switch part 25 is completed as illustrated in FIG. 8D.

According to the manufacturing method of this embodiment, the switch electrodes 26a and 26b forming part of the switch part 25 are formed simultaneously with the patterns 18. Therefore, it is possible to form the switch part 25 in the board body 11B in a shorter period of time and with more efficiency than the conventional method of mounting the switch 3 separately on the substrate 1. (See FIG. 1.) Further, according to the manufacturing method of this embodiment as well, it is possible to reduce manufacturing cost because the manufacturing process is simpler than it has been conventionally.

### [c] Third Embodiment

Next, a description is given of a mechanical component-containing board 10C according to a third embodiment of the present invention.

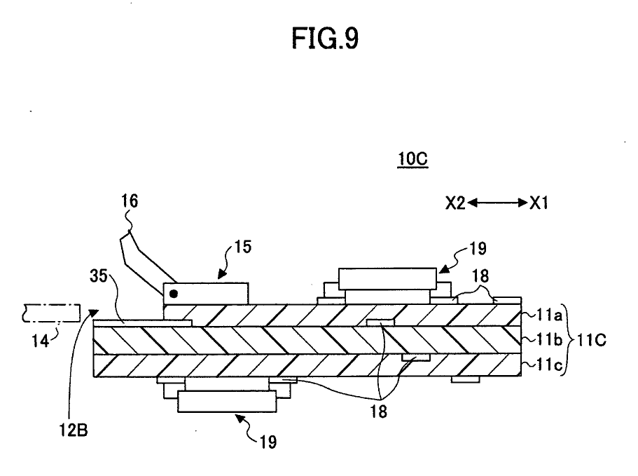

FIG. 9 is a cross-sectional view of the mechanical component-containing board 10C according to the third embodiment. In FIG. 9 as well, elements or configurations corresponding to those of the mechanical component-containing board 10A of the first embodiment illustrated in FIG. 4 are referred to by the same reference numerals, and further description thereof is omitted.

The mechanical component-containing board 10C according to this embodiment has a connector part 12B as a mechanical component built in a board body 11C. In the above-described mechanical component-containing board 10A according to the first embodiment, the connector terminal 17, which forms part of the connector part 12A provided in the mechanical component-containing board 10A, is built in and integrated with the board body 11A. On the other hand, according to the mechanical component-containing board 10C of this embodiment, a connector terminal 35 forming part of the connector part 12B is the same as the patterns formed in and on the board body 11C, and the connector terminal 35 is provided using part of these patterns 18.

Thus, in the mechanical component-containing board 10C according to this embodiment, the connector terminal 35 forming part of the connector part 12B is formed using part of the patterns 18 of the board body 11C. This allows the connector part 12B and the board body 11C to share their constituent component. Accordingly, it is possible to reduce the size and thickness of the mechanical component-containing board 10C, and it is possible to reduce product cost compared with the conventional configuration of manufacturing the connector 2 or 5 and the substrate 1 separately. (See FIG. 1 or FIG. 2.)

In the above description of this embodiment, the connector part 12B, which is a connecting unit, is taken as an example of the mechanical component to be built in the board body 11C. Alternatively, it is also possible to have another type of connecting unit (such as a socket) built in the board body 11C.

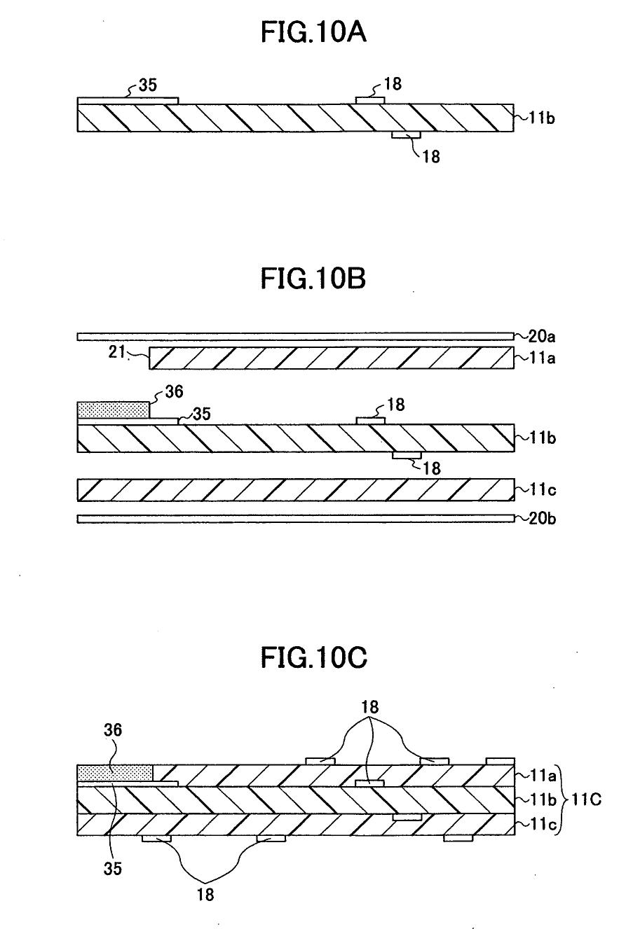

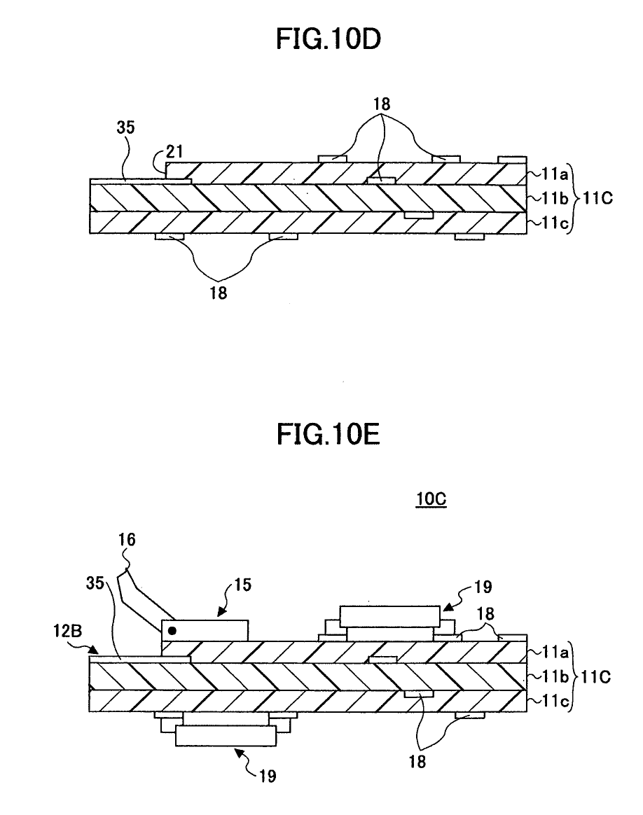

Next, a description is given, with reference to FIGS. 10A through 10E, of a method of manufacturing the above-described mechanical component-containing board 10C. In FIGS. 10A through 10E as well, elements or configurations corresponding to those illustrated in FIGS. 5A through 5E used for the above description are referred to by the same reference numerals, and further description thereof is omitted.

In manufacturing the mechanical component-containing board 10C, first, the base 11b is manufactured. Specifically, copper foil is provided on the top and bottom surfaces of prepreg or an adhesive agent to serve as the base material of the base 11b, and the copper foil is patterned into a predetermined shape using etching. By this copper foil patterning, the patterns 18 and the connector terminal 35 forming part of the connector part 12B are formed on the base 11b. Thus, the patterns 18 and the connector terminal 35, which have the same quality of material, are simultaneously formed in a collective manner. FIG. 10A illustrates the base 11b having the patterns 18 and the connector terminal 35 formed thereon.

Once the connector terminal 35 is provided on the base 11b as described above, the copper foil 20a, the base 11a, the base 11b, the base 11c, and the copper foil 20b are stacked in layers in this order from top to bottom as illustrated in FIG. 10B. This layered body is subjected to joining processing while being pressed, so that the bases 11a through 11c are integrated into a unitary structure.

At this point, the opening part 21 is preformed at a position where the connector part 12B is to be formed in the base 11a, and the stacking process is performed with a dummy member 36 being provided in the opening part 21 at the time of stacking. The connector terminal 35 is formed at a position where the connector part 12B is to be formed on the base 11b. Therefore, the stacking is performed with a predetermined area of the connector terminal 35 being covered with the dummy member 36. The dummy member 36 is formed of the same material as the above-described dummy component 23 (for example, FIG. 6B).

By thus stacking the bases 11a through 11c in layers, the portion of the connector terminal 35 exposed outside the dummy member 36 is embedded and fixed between the base 11a and the base 11b. Further, since the dummy member 36 is substantially equal in thickness to the base 11a, the upper surface of the dummy member 36 is substantially level with the upper surface of the base 11a with the bases 11a through 11c being stacked in layers.

When the above-described stacking process is completed, next, the copper foil 20a and the copper foil 20b are patterned by etching, so that the patterns 18 of predetermined shapes are formed on the upper surface of the base 11a and the lower surface of the base 11c. FIG. 10C illustrates a structure where the patterns 18 are formed on the upper surface of the base 11a and the lower surface of the base 11c.

Next, the dummy member 36 is removed. As described above, the dummy member 36 is formed of the same material as the dummy component 23. Thus, the dummy member 36 is formed of a material that can be dissolved by an etching agent. Therefore, it is possible to selectively remove the dummy member 36 by etching with an etching agent.

By the completion of the removal of the dummy member 36, the board body 11C integrated with the built-in connector terminal 35 forming part of the connector part 12B, that is, having the connector terminal 35 provided using part of the patterns 18, is manufactured. FIG. 10D illustrates the manufactured board body 11C.

Next, the pressure contact component 15 is mounted on the upper surface of the base 11a, and the electronic components 19 are mounted on the upper surface of the base 11a and the lower surface of the base 11c. As a result, the mechanical component-containing board 10C integrated with the built-in connector part 12B is completed as illustrated in FIG. 10E.

According to the manufacturing method of this embodiment, the connector terminal 35 forming part of the connector part 12B is formed simultaneously with the patterns 18. Therefore, it is possible to form the connector part 12B in the board body 11C in a shorter period of time and with more efficiency than the conventional method of mounting the connector 2 or 5 separately on the substrate 1. (See FIG. 1 or FIG. 2.) Further, according to the manufacturing method of this embodiment as well, it is possible to reduce manufacturing cost because the manufacturing process is simpler than it has been conventionally.

### [d] Fourth Embodiment

Next, a description is given of a mechanical component-containing board 10D according to a fourth embodiment of the present invention.

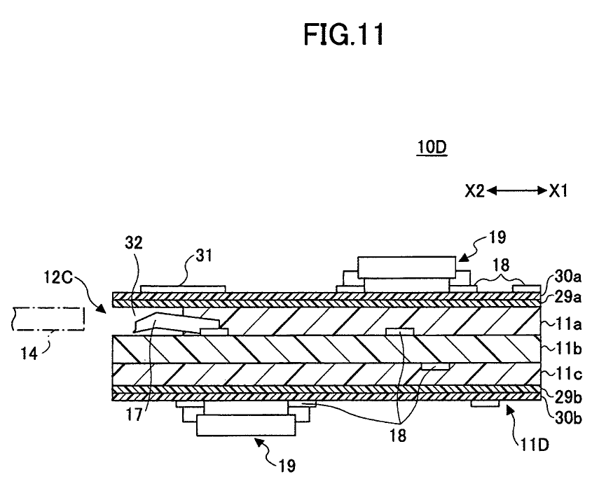

FIG. 11 is a cross-sectional view of the mechanical component-containing board 10D according to the fourth embodiment. In FIG. 11 as well, elements or configurations corresponding to those of the mechanical component-containing board 10A of the first embodiment illustrated in FIG. 4 are referred to by the same reference numerals, and further description thereof is omitted.

The mechanical component-containing board 10D according to this embodiment has a connector part 12C as a mechanical component built in a board body 11D. The above-described connector part 12A provided in the mechanical component-containing board 10A of the first embodiment has the pressure contact component 15 provided to hold the FPC 14 to be attached (connected) to the connector part 12A.

On the other hand, according to the mechanical component-containing board 10D of this embodiment, the board body 11D includes a cover film 29a and a surface base 30a, and the FPC 14 to be attached to the connector part 12C is held by the cover film 29a and the surface base 30a. Further, a reinforcement pattern 31 is provided on the surface base 30a above a position where the connector part 12C is formed in order to further ensure the holding of the attached FPC 14 with the cover film 29a and the surface base 30a.

Further, according to the mechanical component-containing board 10D, the connector terminal 17, which is part of the connector part 12C serving as a mechanical component, is built in and integrated with the board body 11D, and part of the patterns 18 forming part of the board body 11D is used directly as the reinforcement pattern 31 of the connector part 12C serving as a mechanical component.

Therefore, according to the mechanical component-containing board 10D of this embodiment as well, it is possible to reduce the size and thickness of the mechanical component-containing board 10D because a constituent component (connector terminal 17) of the connector part 12C is integrated with the board body 11D into a unitary structure, and a constituent component (corresponding pattern 18) of the board body 11D is also used as a component (connector terminal 17) of the connector part 12C. Further, according to this embodiment as well, it is possible to reduce product cost compared with the conventional configuration of manufacturing the connector 2 or 5 and the substrate 1 separately. (See FIG. 1 or FIG. 2.)

In the above description of this embodiment, the connector part 12C, which is a connecting unit, is taken as an example of the mechanical component to be built in the board body 11D. Alternatively, it is also possible to have another type of connecting unit (such as a socket) built in the board body 11D.

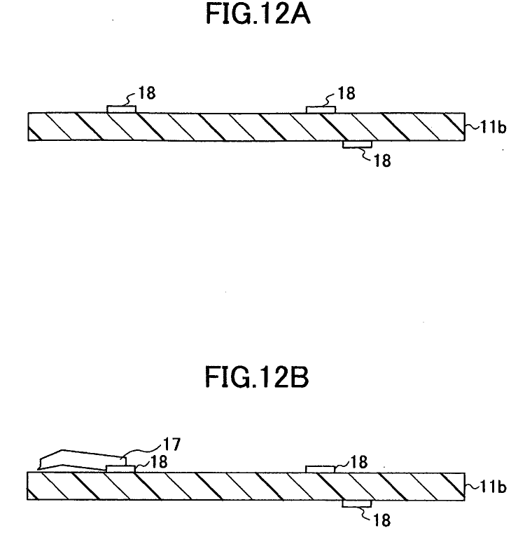

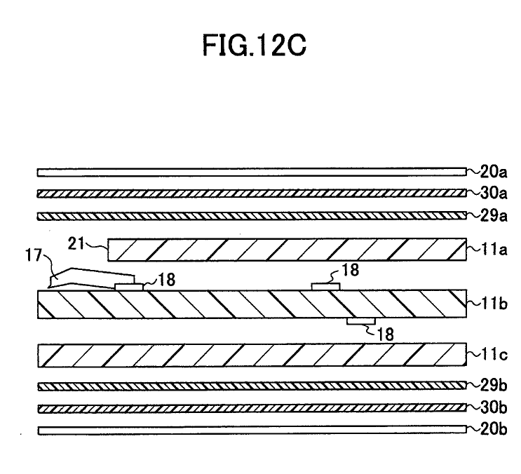

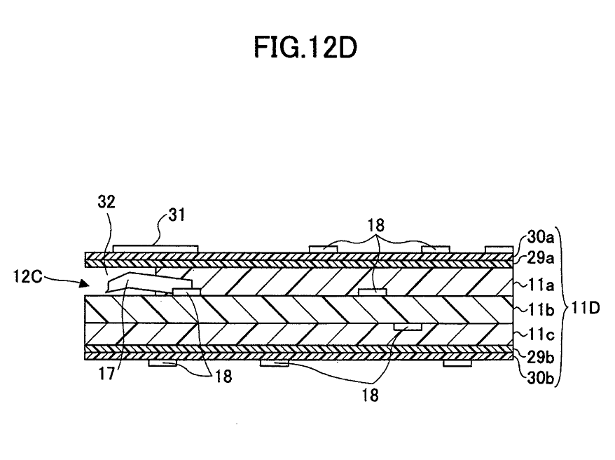

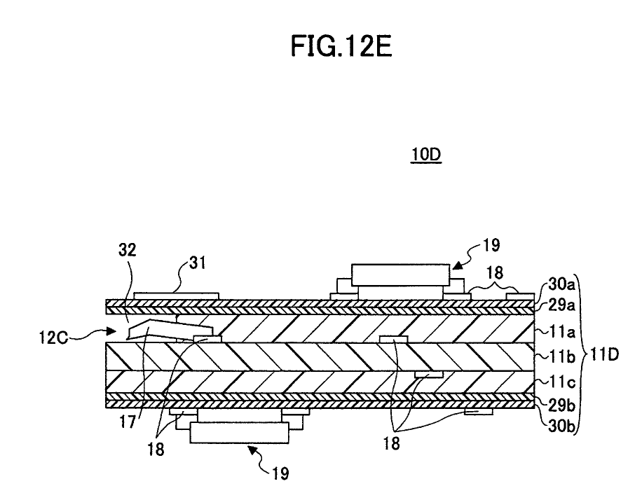

Next, a description is given, with reference to FIGS. 12A through 12E, of a method of manufacturing the above-described mechanical component-containing board 10D. In FIGS. 12A through 12E, elements or configurations corresponding to those illustrated in FIGS. 5A through 5E are referred to by the same reference numerals, and further description thereof is omitted.

In manufacturing the mechanical component-containing board 10D, copper foil is provided on the top and bottom surfaces of prepreg or an adhesive agent to serve as the base material of the base 11b, and the copper foil is patterned into a predetermined shape using etching, thereby forming the patterns 18. FIG. 12A illustrates the base 11b having the patterns 18 formed thereon.

When the base 11b is formed, next, the connector terminal 17 is provided on the base 11b. FIG. 12B illustrates a structure where the connector terminal 17 is provided on the base 11b, being joined to the corresponding pattern 18. The above-described processes are the same as those illustrated in FIGS. 5A and 5B.

Once the connector terminal 17 is provided on the base 11b as described above, the copper foil 20a, the surface base 30a, the cover film 29a, the base 11a, the base 11b, the base 11c, a cover film 29b, a surface base 30b, and the copper foil 20b are stacked in layers in this order from top to bottom as illustrated in FIG. 12C. This layered body is subjected to joining processing while being pressed, so that the surface base 30a, the cover film 29a, the bases 11a through 11c, the cover film 29b, and the surface base 30b are integrated into a unitary structure. The cover films 29a and 29b and the surface bases 30a and 30b are resin films of, for example, polyimide.

By stacking the surface base 30a, the cover film 29a, the bases 11a through 11c, the cover film 29b, and the surface base 30b in layers as described above, part of the connector terminal 17, specifically, an inside (right-side in FIG. 12D) portion of the connector terminal 17, is embedded between the base 11a and the base 11b. Further, the cover film 29a and the surface base 30a extend to a position to cover the opening part 21 formed in the base 11a.

When the above-described stacking process is completed, next, the copper foil 20a and the copper foil 20b are patterned by etching, so that the patterns 18 of predetermined shapes are formed on the upper surface of the surface base 30a and the lower surface of the surface base 30b. Simultaneously, the reinforcement pattern 31 is formed at a position opposed to where the connector part 12C is to be formed on the upper surface of the base 11a. As a result, the board body 11D is manufactured that is integrated with the built-in connector terminal 17, which forms part of the connector part 12A, and has the reinforcement pattern 31 formed simultaneously with the patterns 18 (on the upper surface of the surface base 30a and the lower surface of the surface base 30b). FIG. 12D illustrates the manufactured board body 11D.

Once the board body 11D is manufactured as described above, the electronic components 19 are mounted on the upper surface of the surface base 30a and the lower surface of the surface base 30b. As a result, the mechanical component-containing board 10D integrated with the built-in connector part 12C is completed as illustrated in FIG. 12E.

According to the manufacturing method of this embodiment, the connector terminal 17 forming part of the connector part 12C is incorporated into the board body 11D during the manufacture of the board body 11D, and the reinforcement pattern 31 forming part of the connector part 12C is formed simultaneously with the patterns 18 (on the upper surface of the surface base 30a and the lower surface of the surface base 30b). That is, part of the manufacturing process of the connector part 12C and part of the manufacturing process of the board body 11D are performed simultaneously. Therefore, according to this embodiment as well, it is possible to form the connector part 12C in the board body 11D in a shorter period of time and with more efficiency than the conventional method of mounting the connector 2 or 5 separately on the substrate 1. (See FIG. 1 or FIG. 2.) Further, according to the manufacturing method of this embodiment, it is also possible to reduce manufacturing cost because of a simplified manufacturing process.

According to an aspect of an embodiment of the present invention, part of a mechanical component is built in and integrated with a board body or part of the board body is used as part of the mechanical component. As a result, it is possible for the mechanical component and the board body to share their constituent component. Accordingly, it is possible to reduce the size and thickness of a mechanical component-containing board and to reduce its production (manufacturing cost). That is, it is possible to provide a mechanical component-containing board reduced in size and thickness at low cost.

According to one embodiment of the present invention, a method of manufacturing a mechanical component-containing board includes forming a first base having a pattern formed thereon, a second base having a pattern and a switch electrode to form a switch formed simultaneously thereon, and a third base having an opening part formed where the switch is to be formed; and forming a board body by providing one of an anisotropic conductive sheet and a pressure sensor in the opening part of the third base and stacking the first through third bases in layers so that the one of the anisotropic conductive sheet and the pressure sensor is opposed to the switch electrode.

Additionally, the method as set forth above may further include forming an additional switch electrode on a first surface of the one of the anisotropic conductive sheet and the pressure sensor facing away from the switch electrode by patterning copper foil simultaneously with or after stacking the first through third bases, wherein the switch electrode may be opposed to a second surface of the one of the anisotropic conductive sheet and the pressure sensor facing away from the first surface in stacking the first through third bases.

According to one embodiment of the present invention, a method of manufacturing a mechanical component-containing board includes forming a first base having a pattern formed thereon and a second base having a pattern formed thereon and a part of a mechanical component formed integrally therewith; and forming a board body having the part of the mechanical component built therein and integrated therewith by stacking the first and second bases in layers.

Additionally, the method as set forth above may further include providing the board body with a holding component configured to hold a device to be attached to the mechanical component after completion of stacking the first and second bases, wherein the mechanical component may be one of a connector and a socket including a connection terminal and the holding component, and the connection terminal and the second base may be formed as a unit in forming the part of the mechanical component integrally with the second base.

Additionally, the method as set forth above may further include removing a dummy member after completion of stacking the first and second bases, wherein the mechanical component may be one of a connector and a socket including a connection terminal and a holding component configured to hold a device to be attached to the one of the connector and the socket, the connection terminal and the second base may be formed as a unit in forming the part of the mechanical component integrally with the second base, and the first and second bases may be stacked with the dummy member provided on the connection terminal in stacking the first and second bases.

According to one embodiment of the present invention, a mechanical component-containing board includes a board body; and a mechanical component, wherein the mechanical component has a part thereof built in and integrated with the board body, and the board body has a part thereof used as the part of the mechanical component.

Additionally, in the mechanical component-containing board as set forth above, the board body may include a pattern, the mechanical component may be one of a connector and a socket including a connection terminal and a reinforcement member configured to hold a device to be attached to the one of the connector and the socket at an attachment position, the connection terminal may be built in and integrated with the board body, and a part of the pattern formed on the board body may be used as the reinforcement member.

According to one embodiment of the present invention, a method of manufacturing a mechanical component-containing board includes forming a plurality of bases having a pattern formed thereon; providing at least one of the bases with a part of a mechanical component; forming a board body having the part of the mechanical component built therein and integrated therewith by stacking the bases and a conductive film in layers; and forming a reinforcement member and the pattern by patterning the conductive film.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions has (have) been described in detail, it should be understood that various changes, substitutions, and alterations could be made hereto without departing from the spirit and scope of the invention.

What is claimed is:

1. A mechanical component-containing board, comprising:
a board body; and
a mechanical component having a part thereof built in and integrated with the board body.

2. The mechanical component-containing board as claimed in claim 1, wherein:
the mechanical component is a connecting unit including a connection terminal, and
the connection terminal is built in and integrated with the board body.

3. The mechanical component-containing board as claimed in claim 1, wherein:
the mechanical component is one of a connector and a socket including a connection terminal and a pressure contact member configured to press and contact a device to be attached to the one of the connector and the socket,
the connection terminal is built in and integrated with the board body, and
the pressure contact member is provided on the board body.

4. The mechanical component-containing board as claimed in claim 1, further comprising:
an electronic component mounted on the board body.

5. The mechanical component-containing board as claimed in claim 1, wherein the board body is a layered board including a plurality of bases stacked in layers.

6. A method of manufacturing a mechanical component-containing board, the method comprising:
forming a plurality of bases having a pattern formed thereon;
providing at least one of the bases with a part of a mechanical component; and
forming a board body having the part of the mechanical component built therein and integrated therewith by stacking the bases in layers.

7. The method as claimed in claim 6, further comprising:
providing the board body with a holding component configured to hold a member to be attached to the mechanical component after completion of stacking the bases,
wherein the mechanical component is one of a connector and a socket including a connection terminal, and
the connection terminal is provided on the at least one of the bases in providing the at least one of the bases with the part of the mechanical component.

8. The method as claimed in claim 6, further comprising:
removing a dummy component after completion of stacking the bases,
wherein the mechanical component is one of a connector and a socket including a connection terminal, and
a component including the connection terminal and the dummy component holding the connection terminal is provided on the at least one of the bases in providing the at least one of the bases with the part of the mechanical component.

9. A mechanical component-containing board, comprising:
a board body; and
a mechanical component,
wherein the board body has a part thereof used as a part of the mechanical component.

10. The mechanical component-containing board as claimed in claim 9, wherein:
the board body includes a pattern,
the mechanical component is a switch including a switch electrode, and
a part of the pattern of the board body is used as the switch electrode.

11. The mechanical component-containing board as claimed in claim 9, wherein:
the board body includes a pattern,
the mechanical component is a switch including a pair of switch electrodes and one of an anisotropic conductive sheet and a pressure sensor provided between the switch electrodes, and
a part of the pattern of the board body is used as the switch electrodes.

12. The mechanical component-containing board as claimed in claim 9, further comprising:
an electronic component mounted on the board body.

13. The mechanical component-containing board as claimed in claim 9, wherein the board body is a layered board including a plurality of bases stacked in layers.

14. The mechanical component-containing board as claimed in claim 9, wherein:
the board body includes a pattern,
the mechanical component is one of a connector and a socket including a connection terminal, and
a part of the pattern is used as the connection terminal.

15. The mechanical component-containing board as claimed in claim 9, further comprising:
a pressure contact component configured to hold a member to be attached to the mechanical component by pressing and contacting the member,
wherein the board body includes a pattern,
the mechanical component is one of a connector and a socket including a connection terminal, and
a part of the pattern is used as the connection terminal.
